(19) United States
(12) Patent Application Publication
(10) Pub. No.: US 2012/0193238 A1
(43) Pub. Date: Aug. 2, 2012

(54) Compositions For Plating Copper And Methods Of Forming A Copper Bump Using The Same

(75) Inventors: Myung-Beom Park, Hwaseong-si (KR); Ki-Hyeon Kim, Seoul (KR); Jung-Sik Choi, Seongnam-si (KR); Jung-Ho Lee, Suwon-si (KR)

(73) Assignee: SAMSUNG ELECTRONICS CO., LTD., Suwon-si (KR)

(21) Appl. No.: 13/287,434

(22) Filed: Nov. 2, 2011

(30) Foreign Application Priority Data
Jan. 31, 2011 (KR) 10-2011-0009251

(51) Int. Cl. C25D 3/38; C25D 17/00; C25D 5/02

(52) U.S. Cl. 205/118; 205/297; 204/242; 204/273

(57) ABSTRACT

A composition for plating copper includes an electrolyte solution, an accelerator, a suppressor and a leveler. The electrolyte solution includes a soluble copper salt, sulfuric acid and hydrochloric acid. The accelerator includes about 20 to about 60 ppm of a disulfide compound. The suppressor includes about 40 to about 100 ppm of a polyethyleneoxide (PEO)-polypropyleneoxide (PPO)-polyethyleneoxide (PEO) triblock copolymer. The PEO-PPO-PEO triblock copolymer has a weight average molecular weight of about 300 to about 10,000. The leveler includes about 0.01 to about 100 ppm of arylated polyethyleneimine.

### CROSS-REFERENCE TO RELATED APPLICATION

This application claims priority under 35 USC §119 to Korean Patent Application No. 10-2011-0009251 filed on Jan. 31, 2011 in the Korean Intellectual Property Office (KIPO), the entire contents of which are herein incorporated by reference.

### BACKGROUND

1. Field

Some example embodiments relate to compositions for plating copper and methods of forming a copper bump using the same. More particularly, some example embodiments relate to compositions for plating copper with a relatively high speed and methods of forming a copper bump using the same.

2. Description of the Related Art

For mass-production of flip-chip packages at lower costs, technologies of plating a metal, e.g., copper (Cu) or nickel (Ni), with a higher speed have been developed. For example, a bump serving as a connecting element in the flip-chip package may be formed by plating a metal, e.g., copper. However, a larger current may be required for the plating process with a higher speed so that the bump may grow abnormally, and a surface roughness of the bump may be increased.

### SUMMARY

Some example embodiments provide a composition for plating copper employed for uniform plating at a high speed. Other example embodiments provide a method of forming a copper bump using the composition.

According to an example embodiment, there is provided a composition for plating copper. The composition for plating copper includes an electrolyte solution, an accelerator, a suppressor and a leveler. The electrolyte solution includes a soluble copper salt, sulfuric acid and hydrochloric acid. The accelerator includes about 20 to about 60 ppm of a disulfide compound. The suppressor includes about 40 to about 100 ppm of a polyethylene oxide (PEO)-polypropylene oxide (PPO)-polyethylene oxide (PEO) triblock copolymer. The PEO-PPO-PEO triblock copolymer has a weight average molecular weight of about 300 to about 10,000. The leveler includes about 0.01 to about 100 ppm of arylated polyethyleneimine.

In an example embodiment, the disulfide compound may be represented by Chemical Formula (1):

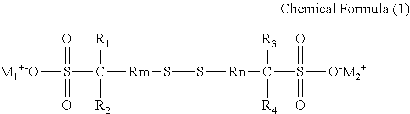

In the Chemical Formula (1), R₁ and R₃ may independently represent a methyl group, an ethyl group, a propyl group, an isopropyl group, an n-butyl group, a sec-butyl group, a tert-butyl group or a trimethylsilyl group. R₂ and R₄ may independently represent hydrogen, a methyl group, an ethyl group, a propyl group, an n-butyl group, a sec-butyl group, a tert-butyl group or a trimethylsilyl group. Rm and Rn may independently represent a C₁-C₁₀ alkylene, a C₃-C₁₀ cycloalkylene or a C₄-C₁₀ aromatic hydrocarbon. M¹⁺ and M²⁺ independently represent proton, an alkali metal ion or ammonium ion.

In an example embodiment, the disulfide compound may include bis-(3-sulfo-3-methylpropyl)disulfide dipotassium salt (Me-SPS).

In an example embodiment, the soluble copper salt may include copper (II) sulfate pentahydrate (CuSO₄.5H₂O). The electrolyte solution may include about 50 to about 70 g/L of copper (II) sulfate pentahydrate, about 40 to about 60 g/L of sulfuric acid and about 40 to about 60 g/L of hydrochloric acid.

In an example embodiment, the PEO-PPO-PEO triblock copolymer may have a weight average molecular weight of about 2,500 to about 5,000 and a content of ethylene oxide (EO %) in a range of about 30 to about 60% (w/w).

According to another example embodiment, there is provided a method of forming a copper bump. In the method, an insulation layer is formed on a substrate. The insulation layer includes an electrode pad therein. A mask is formed on the insulation layer. The mask includes an opening therein that exposes the electrode pad. An electroplating process is performed using a composition for plating copper to form a copper plated layer filling the opening. The composition for plating copper includes an electrolyte solution, an accelerator, a suppressor and a leveler. The electrolyte solution includes a soluble copper salt, sulfuric acid and hydrochloric acid. The accelerator includes about 20 to about 60 ppm of a disulfide compound. The suppressor includes about 40 to about 100 ppm of a polyethylene oxide (PEO)-polypropylene oxide (PPO)-polyethylene oxide (PEO) triblock copolymer. The PEO-PPO-PEO triblock copolymer has a weight average molecular weight of about 300 to about 10,000. The leveler includes about 0.01 to about 100 ppm of arylated polyethyleneimine.

In another example embodiment, the disulfide compound may be represented by Chemical Formula (1):

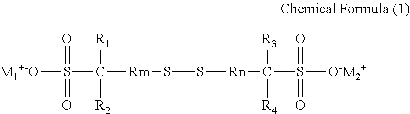

In the Chemical Formula (1), R₁ and R₃ may independently represent a methyl group, an ethyl group, a propyl group, an isopropyl group, an n-butyl group, a sec-butyl group, a tert-butyl group or a trimethylsilyl group. R₂ and R₄ may independently represent hydrogen, a methyl group, an ethyl group, a propyl group, an n-butyl group, a sec-butyl group, a tert-butyl group or a trimethylsilyl group. Rm and Rn may independently represent a C₁-C₁₀ alkylene, a C₃-C₁₀ cycloalkylene or a C₄-C₁₀ aromatic hydrocarbon. M¹⁺ and M²⁺ independently represent proton, an alkali metal ion or ammonium ion.

In another example embodiment, the disulfide compound may include bis-(3-sulfo-3-methylpropyl)disulfide dipotassium salt (Me-SPS).

In another example embodiment, the soluble copper salt may include copper (II) sulfate pentahydrate (CuSO₄.5H₂O). The electrolyte solution may include about 50 to about 70 g/L of copper (II) sulfate pentahydrate, about 40 to about 60 g/L of sulfuric acid and about 40 to about 60 g/L of hydrochloric acid.

In another example embodiment, the PEO-PPO-PEO triblock copolymer may have a weight average molecular weight of about 2,500 to about 5,000 and a content of ethylene oxide (EO %) in a range of about 30 to about 60% (w/w).

In another example embodiment, in the electroplating process, a plating solution that includes the composition for plating copper may be provided onto the substrate at a flow rate of about 0.1 to about 300 L/min.

In another example embodiment, the electroplating process may be performed at a plating rate of about 3 to about 4 μm/min.

In another example embodiment, the substrate may be maintained at a temperature of about 20 to about 50° C. and the substrate may be rotated at a rate of about 2 to about 100 rpm during the electroplating process.

In another example embodiment, the copper plated layer may include a plurality of copper plated players in the shape of a pillar. Alternatively, the copper plated layer may have a linear shape.

According to yet another example embodiment, there is provided an electroplating apparatus. The electroplating apparatus includes a substrate, a plating bath, a supporter, a dispersion plate, and a voltage supplier. The plating bath is configured to receive a plating solution containing a composition for plating copper on the substrate. Located in an upper portion of the plating bath, the supporter is configured to support the substrate and function as a cathode. Located in a lower portion of the plating bath, the dispersion plate is configured to function as an anode. The voltage supplier is connected to the supporter and the dispersion plate. The composition for plating copper includes an electrolyte solution, an accelerator, a suppressor and a leveler. The electrolyte solution includes a soluble copper salt, sulfuric acid and hydrochloric acid. The accelerator includes about 20 to about 60 ppm of a disulfide compound. The suppressor includes about 40 to about 100 ppm of a polyethylene oxide (PEO)-polypropylene oxide (PPO)-polyethylene oxide (PEO) triblock copolymer. The PEO-PPO-PEO triblock copolymer has a weight average molecular weight of about 300 to about 10,000. The leveler includes about 0.01 to about 100 ppm of arylated polyethyleneimine.

In yet another example embodiment, the electroplating apparatus may further include a mixer, a flow rate controller, a collector, a first plating solution transfer line and a second plating solution transfer line. The mixer is connected to the plating bath, and is configured to mix the composition for plating copper. The flow rate controller is connected to the mixer, and configured to adjust a flow rate of the plating solution. The collector is on sides of the plating path, and configured to collect or recycle the plating solution. The first plating solution transfer line is configured to connect the plating bath to the flow rate controller, and the second plating solution transfer line is configured to connect both the plating bath to the collector and the collector to the mixer.

In yet another example embodiment, the disulfide compound may be represented by Chemical Formula (1):

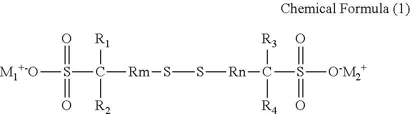

In the Chemical Formula (1), R₁ and R₃ may independently represent a methyl group, an ethyl group, a propyl group, an isopropyl group, an n-butyl group, a sec-butyl group, a tert-butyl group or a trimethylsilyl group. R₂ and R₄ may independently represent hydrogen, a methyl group, an ethyl group, a propyl group, an n-butyl group, a sec-butyl group, a tert-butyl group or a trimethylsilyl group. Rm and Rn may independently represent a C₁-C₁₀ alkylene, a C₃-C₁₀ cycloalkylene of a C₄-C₁₀ aromatic hydrocarbon. M¹⁺ and M²⁺ independently represent proton, an alkali metal ion or ammonium ion.

In yet another example embodiment, the soluble copper salt may include copper (II) sulfate pentahydrate (CuSO₄.5H₂O). The electrolyte solution may include about 50 to about 70 g/L of copper (II) sulfate pentahydrate, about 40 to about 60 g/L of sulfuric acid and about 40 to about 60 g/L of hydrochloric acid.

In yet another example embodiment, the PEO-PPO-PEO triblock copolymer may have a weight average molecular weight of about 2,500 to about 5,000 and a content of ethylene oxide (EO %) in a range of about 30 to about 60% (w/w).

### BRIEF DESCRIPTION OF THE DRAWINGS

Example embodiments will be more clearly understood from the following detailed description taken in conjunction with the accompanying drawings. FIGS. 1 to 10 represent non-limiting, example embodiments as described herein.

FIG. 1 is a cross-sectional view illustrating an electroplating apparatus for plating copper in accordance with an example embodiment;

FIGS. 2 to 4 and 7 are cross-sectional views illustrating a method of forming a copper bump in accordance with another example embodiment;

FIGS. 5 and 6 are top plan views illustrating the copper bump formed by the method in accordance with another example embodiment;

FIG. 8 is a scanning electron microscope (SEM) picture of a copper bump formed using a composition for plating copper of a comparative example;

FIG. 9 is a SEM picture of a copper bump formed using a composition for plating copper of Example 1; and

FIG. 10 is a SEM picture of a copper bump formed using a composition for plating copper of Example 2.

### DETAILED DESCRIPTION OF EXAMPLE EMBODIMENTS

Various example embodiments will be described more fully hereinafter with reference to the accompanying drawings, in which some example embodiments are shown. The present inventive concept may, however, be embodied in many different forms and should not be construed as limited to the example embodiments set forth herein. Rather, these example embodiments are provided so that this description will be thorough and complete, and will fully convey the scope of the present inventive concept to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concept.

Spatially relative twins, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concept.

Unless otherwise defined, all terms (including technical and scientific terms) used herein have the same meaning as commonly understood by one of ordinary skill in the art to which this inventive concept belongs. It will be further understood that temis, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments will be explained in detail with reference to the accompanying drawings.

### Compositions for Plating Copper

A composition for plating copper according to an example embodiment may include an electrolyte solution, an accelerator, a suppressor and a leveler.

The electrolyte solution may include sulfuric acid and hydrochloric acid in which soluble copper salts providing copper ions may be dissolved. The soluble copper salts may include copper (II) sulfate pentahydrate (CuSO₄.5H₂O). For example, the electrolyte solution may include copper (II) sulfate pentahydrate having a concentration of about 50 to about 70 g/L by weight of copper, sulfuric acid having a concentration of about 40 to about 60 g/L and hydrochloric acid having a concentration of about 40 to about 60 g/L.

The accelerator may include a disulfide compound represented by the following Chemical Formula (1).

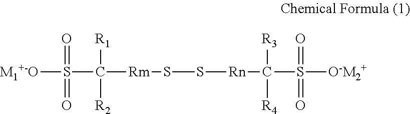

In Chemical Formula (1), R₁ and R₃ may independently represent a methyl group, an ethyl group, a propyl group, an isopropyl group, an n-butyl group, a sec-butyl group, a tert-butyl group or a trimethylsilyl group. R₂ and R₄ may independently represent hydrogen, a methyl group, an ethyl group, a propyl group, an n-butyl group, a sec-butyl group, a tert-butyl group or a trimethylsilyl group. Rm and Rn may independently represent a C₁-C₁₀ alkylene, a C₃-C₁₀ cycloalkylene or a C₄-C₁₀ aromatic hydrocarbon. M¹⁺ and M²⁺ may independently represent a proton, an alkali metal ion or an ammonium ion.

The disulfide compound may include, e.g., bis-(3-sulfo-3-methylpropyl)disulfide salts, bis-(3-sulfo-3-ethylpropyl)disulfide salts, bis-(3-sulfo-3-isopropyl)disulfide salts, bis-(3-sulfo-3-t-butylpropyl)disulfide salts, bis-(3-sulfo-3-trimethylsilylpropyl)disulfide salts, bis-(3-sulfo-3,3-dimethylpropyl)disulfide salts, bis-(3-sulfo-3,3-diethylpropyl) disulfide salts, bis-(2-sulfo-2-methylethyl)disulfide salts, bis-(2-sulfo-2-ethylmethyl) disulfide salts, bis-(4-sulfo-4-methylbutyl)disulfide salts, bis-(4-sulfo-4-ethylbutyl)disulfide salts, bis-(5-sulfo-5-methylpentyl)disulfide salts, bis-(6-sulfo-6-methylhexyl)disulfide salts, 3-sulfo-3-methylpropyl 4-sulfo-4-methylbutyl disulfide salts, 2-sulfo-2-methylpropyl 3-sulfo-3-methylpropyl disulfide salts, etc. These may be used alone or in a mixture thereof.

In an example embodiment, the disulfide compound may have a concentration of about 20 ppm to about 60 ppm. If the concentration of the disulfide compound is less than about 20 ppm, a plated layer may be adsorbed to have a convex upper surface. If the concentration of the disulfide compound exceeds about 60 ppm, the cost of the composition for plating copper may be increased.

The suppressor may include a copolymer of polyethyleneoxide (PEO) and polypropyleneoxide (PPO). The copolymer of PEO and PPO may include, e.g., a PEO-PPO-PEO triblock copolymer, a PPO-PEO-PPO triblock copolymer, PEO/PPO-PPO/PEO-PEO/PPO tetrablock copolymer, a PPO/PEO-PEO/PPO-PPO/PEO tetrablock copolymer, etc. The suppressor may have a weight average molecular weight of about 100 to about 100,000.

In an example embodiment, the PEO-PPO-PEO triblock copolymer may have a weight average molecular weight of about 300 to about 10,000, and a content of ethylene oxide (BO %) in the PEO-PPO-PEO triblock copolymer may be in a range of about 1 to about 99% (w/w). In another example embodiment, the PEO-PPO-PEO triblock copolymer may have a weight average molecular weight of about 2,500 to about 5,000, and the content of ethylene oxide (EO %) in the PEO-PPO-PEO triblock copolymer may be in a range of about 30 to about 60% (w/w).

In an example embodiment, the PEO-PPO-PEO triblock copolymer may have a concentration of about 40 ppm to about 100 ppm. If the concentration of the PEO-PPO-PEO triblock copolymer is less than about 40 ppm, the surface-roughness of a plated layer may be increased. If the concentration of the PEO-PPO-PEO triblock copolymer exceeds about 100 ppm, a subsequent plating process may not be easily performed due to an excessive inhibiting or suppressing effect.

The leveler may include a betaine compound represented by the following Chemical Formula (2).

R₅-R₆N—R₇SO₃ Chemical Formula (2)

In Chemical Formula (2), R₅ may represent a C₁-C₄ alkyl group, an aromatic hydrocarbon group, a sulfonyl group, a phosphonyl group, an aldehyde group or a carbamide group. R₆ may represent a pyridine. R₇ may represent a C₁-C₄ alkyl, a cycloalkyl, and an aromatic hydrocarbon. R₇ may also represent a C₁-C₄ alkyl, a cycloalkyl, and an aromatic hydrocarbon which are substituted by one substituent selected from the group of a methyl group, an ethyl group, a propyl group, an isopropyl group, an n-butyl group, a sec-butyl group and a tert-butyl group.

The leveler may include, e.g., arylated polyethyleneimine (arylated PEI), sulfopropylated polyethyleneimine (Sulfopropylated PEI), lauryl dimethyl betaine, lauramidopropyl betaine, alkyl amine oxide, 1-(3-sulfopropyl)pyridinium betaine (PPS), 3-formyl-1-(3-sulfopropyl)pyridinium betaine (FPPS), isoquinoline 1-propanesulfonic acid (IQPS), 3-pyridinesulfonic acid (PYSA), nicotinamide N-propylsulfonate (NPS), etc. These may be used alone or in a mixture thereof.

In an example embodiment, the leveler may include arylated PEI having a concentration of about 0.01 to about 100 ppm. If the concentration of arylated PEI is less than about 0.01 ppm, the surface-roughness of a plated layer may be increased. If the concentration of arylated PEI exceeds about 100 ppm, a leveling effect may be lessened.

### Methods of Forming a Copper Bump

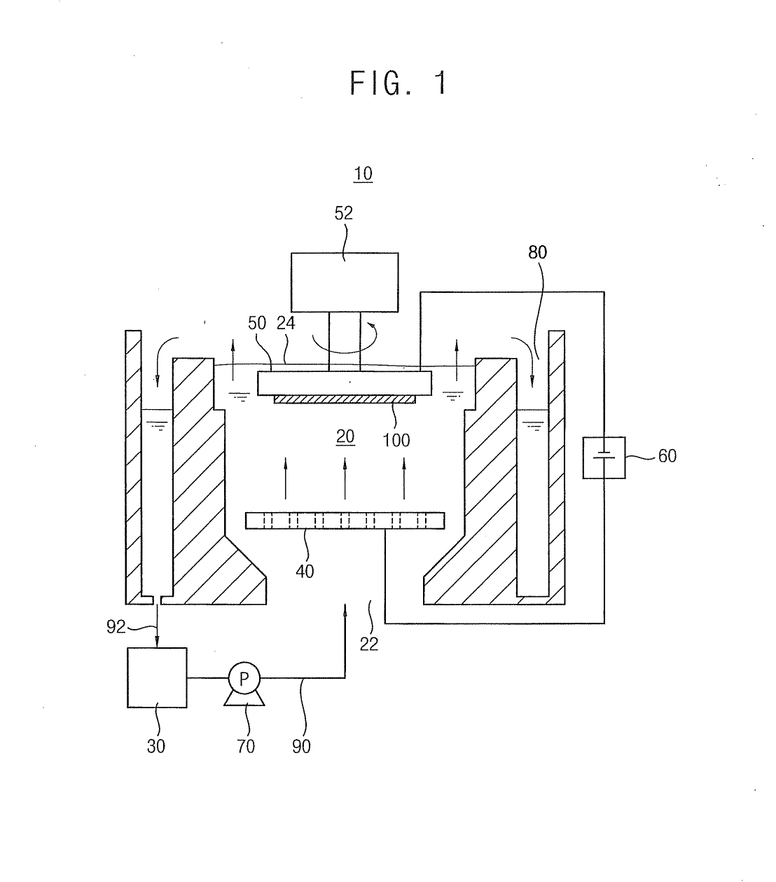

FIG. 1 is a cross-sectional view illustrating an electroplating apparatus for plating copper in accordance with an example embodiment.

Referring to FIG. 1, an electroplating apparatus 10 may include a plating bath 20, a mixer 30, a dispersion plate 40, a supporter 50, a voltage supplier 60, a flow rate controller 70, a collector 80, a first plating solution transfer line 90 and a second plating solution transfer line 92.

The plating bath 20 may receive a plating solution containing a composition for plating copper and a substrate 100 on which a plated layer is deposited. The mixer 30 may be connected to the plating bath 20 to mix an electrolyte solution and additives. The dispersion plate 40 may be located in the plating bath 20 and serve as an anode to disperse the plating solution uniformly on a surface of the substrate 100. The supporter 50 may hold the substrate 100 and serve as a cathode. The voltage supplier 60 may supply voltage to the dispersion plate 40 and the supporter 50. The flow rate controller 70 may adjust a flow rate of the plating solution. The collector 80 may be provided for collecting or recycling the plating solution. The first plating solution transfer line 90 may connect the plating bath 20 to the flow rate controller 70. The second plating solution transfer line 92 may connect the plating bath 20 to the collector 80 or may connect the collector 80 to the mixer 30.

A plating solution supply hole 22 may be connected to a bottom portion of the plating bath 20, and a plating solution collecting hole 24 may be connected to an upper portion of the plating bath 20. A plating solution mixture containing the electrolyte solution and the additives may be supplied from the plating solution supply hole 22, and may be discharged from the plating solution collecting hole 24. The plating solution mixture may be maintained at a temperature of about 20 to about 50° C. The plating solution mixture may have a current density of about 0.1 mA/cm² to about 300 mA/cm² by the voltage supplier 60.

The first and second plating solution transfer lines 90 and 92 may be connected to the plating solution supply hole 22 and the plating solution collecting hole 24, respectively. The plating solution may be introduced to the plating bath 20 by a pump connected to the first plating solution transfer line 90. An input of the plating solution through the first plating solution transfer line 90 may be adjusted by the flow rate controller 70.

The plating solution mixture containing the composition for plating copper may be provided into the plating bath 20 at a flow rate of about 0.1 to about 300 L/min by the flow rate controller 70.

The mixer 30 may be connected to additives suppliers (not illustrated) for providing an accelerator, a suppressor and a leveler such that the additives including the accelerator, the suppressor and the leveler, and the electrolyte solution may be mixed.

The dispersion plate 40 may be disposed adjacent to the plating solution supply hole 22 of the plating bath 20. The dispersion plate 40 may include a plurality of dispersion holes therein. The plating solution mixture provided into the plating bath 20 may pass through the dispersion holes of the dispersion plate 40 to be dispersed uniformly on the substrate 100. The substrate 100 may be supported by the supporter 50, and the supporter 50 may be connected to a rotation driving device 52. Thus, the substrate 100 may be rotated during a plating process at a predetermined or given rate.

The electroplating apparatus 10 may include a plurality of electroplating units (not shown) so that a plurality of semiconductor wafers may be electroplated simultaneously. A copper bump formed by a copper electroplating process using a conventional solution for plating copper may have a surface-roughness greater than about 30% at a plating rate of about 1.5 μm/min. However, the composition for plating copper according to an example embodiment may exhibit a relatively low surface-roughness at a plating rate of about 1.5 μm/min and even at a plating rate of more than about 3 μm/min.

In an example embodiment, the substrate 100 may rotate at a rate of about 2 rpm to about 100 rpm. In another example embodiment, the substrate 100 may rotate at a rate of about 20 rpm to about 60 rpm.

The voltage supplier 60 may be connected to the dispersion plate 40 and the supporter 50. During a copper plating process, the dispersion plate 40 may serve as an anode, and the supporter 50 may serve as a cathode.

The current density applied to the plating solution mixture may be adjusted according to the types of plating processes. In an example embodiment, when the plating process is performed to fill a via or a trench, the current density applied to the plating solution mixture may be adjusted to have a relatively small value of about 0.1 to about 100 mA/cm². In another example embodiment, when the plating process is performed to deposit a layer on a bulk surface, the current density applied to the plating solution mixture may be adjusted to have a relatively large value of about 1 to about 300 mA/cm². Accordingly, the current density applied to a plating solution may be adjusted properly so that uniform plating may be realized in both of a deposition process and a filling process.

The plating solution discharged from the plating solution collecting hole 24 after the plating process may be collected by the collector 80. The second plating solution transfer line 92 may be connected to the plating bath 20 and the collector 80 so that the plating solution collected by the collector 80 may be reused after separation and/or purification processes.

Hereinafter, methods of forming a copper bump using the electroplating apparatus of FIG. 1 will be described.

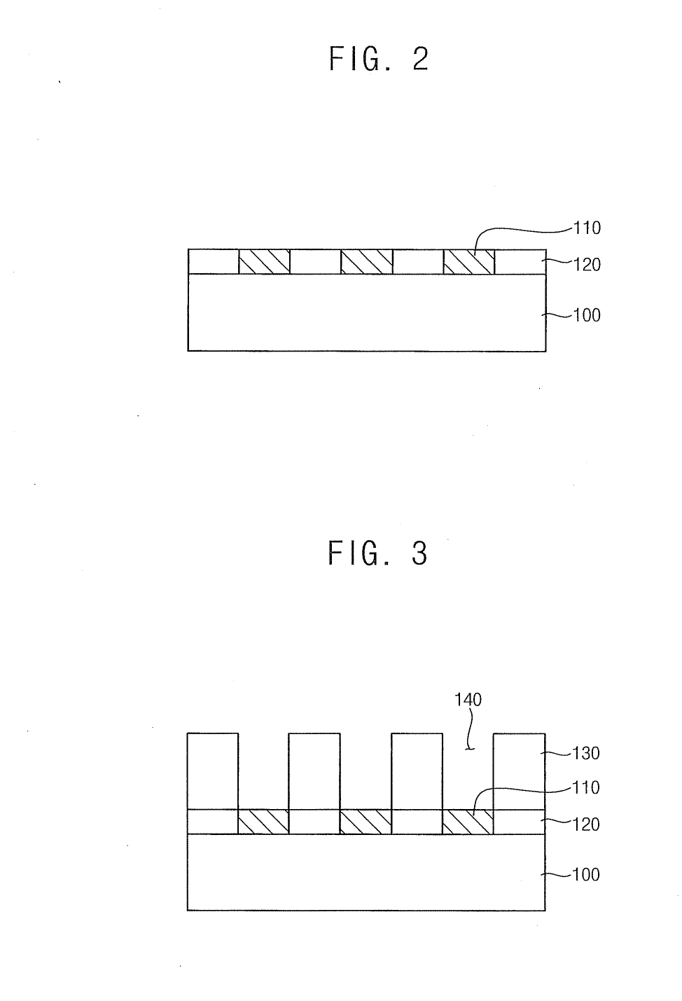

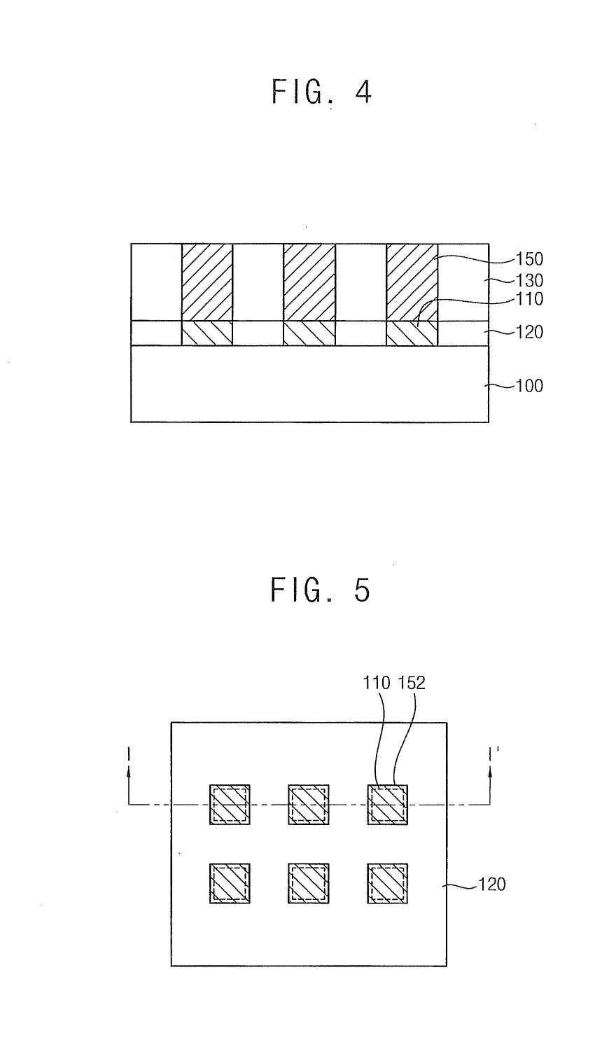

FIGS. 2 to 4 and 7 are cross-sectional views illustrating a method of forming a copper bump in accordance with example embodiments. FIGS. 5 and 6 are top plan views illustrating the copper bump formed by the method in accordance with example embodiments. FIGS. 2 to 4 and 7 are cross-sectional views taken along lines I-I′ in FIGS. 5 and 6.

Referring to FIG. 2, an insulation layer 120 may be formed on a substrate 100, and an electrode pad 110 may be formed through the insulation layer 120 to make contact with the substrate 100. The substrate 100 may include conductive structures (not illustrated), e.g., a plug, a wiring, etc.

The substrate 100 may include silicon substrate, a germanium substrate, a silicon-germanium substrate, a silicon-on-insulator (SOI) substrate, a germanium-on-insulator (GOI) substrate, a single crystalline metal oxide substrate, etc.

The insulation layer 120 may be formed using an insulating material such as an oxide, a nitride and/or an oxynitride. In an example embodiment, the insulation layer 120 may be formed using silicon oxide, e.g., phosphosil cate glass (PSG), borohosphosilicate glass (BPSG), undoped silicate glass (USG), spin on glass (SOG), tetraethyl orthosilicate (TEOS), plasma enhanced-TEOS (PE-TEOS), O₃-TEOS, high density plasma-chemical vapor deposition (HDP-CVD) oxide, etc. In another example embodiment, the insulation layer 120 may be formed using a low-k material having a dielectric constant lower than that of silicon oxide.

For example, the low-k material may include carbon-doped silicon oxide (SiOCH), silicon oxycarbide (SiOC), hydrogenated silicon oxide (SiOH), black diamond, hydrogen silsesquioxane (HSQ), methyl silsesquioxane (MSQ), fluorinated silicate glass (PSG), organic silicate glass (OSG), etc.

In an example embodiment, a hole (not illustrated) exposing a top surface of the substrate 100 may be formed through the insulation layer 120. The hole may be filled with a conductive material to faun the electrode pad 110. In an example embodiment, the conductive material may include copper.

Referring to FIG. 3, a mask 130 including an opening 140 that exposes the electrode pad 110 therethrough may be formed on the insulation layer 120. The opening 140 may also expose a portion of the insulation layer 120.

The mask 130 may be formed using a material having an etching selectivity with respect to the insulation layer 120. For example, the mask 130 may be fanned using a photoresist pattern or a hard mask.

Referring to FIG. 4, a copper plated layer 150 filling the opening 140 may be formed on the electrode pad 110 using a plating solution mixture. In example embodiments, the plating solution mixture may include a composition for plating copper containing an electrolyte solution and additives. The additives may include an accelerator, a suppressor and a leveler.

Particularly, the substrate 100 may be loaded in the electroplating apparatus 10. The electrolyte solution and the additives may be introduced to the mixer 30 and mixed therein to form the plating solution mixture. The mixer 30 may be pre-heated to a temperature of about 20 to about 50° C. to raise the temperature of the plating solution mixture. The plating solution mixture may be provided into the plating bath 20, and the copper plated layer 150 may be deposited on the substrate 100 by an electroplating process.

The electrolyte solution may include sulfuric acid and hydrochloric acid in which soluble copper salts providing copper ions may be dissolved. The soluble copper salts may include copper (II) sulfate pentahydrate (CuSO₄.5H₂O). For example, the electrolyte solution may include copper (II) sulfate pentahydrate having a concentration of about 50 to about 70 g/L based on a weight of copper, sulfuric acid having a concentration of about 40 to about 60 g/L and hydrochloric acid having a concentration of about 40 to about 60 g/L.

The accelerator may serve as a catalyst in a reductive reaction of copper to facilitate the deposition of copper. The suppressor may suppress the growth of copper or the mobility of copper ions. The leveler may reduce the deposition rate of copper and planarize a top surface of the copper plated layer 150.

The accelerator may include a disulfide compound represented by the following Chemical Formula (1).

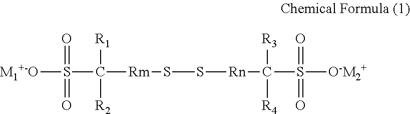

In Chemical Formula (1), R₁ and R₃ may independently represent a methyl group, an ethyl group, a propyl group, an isopropyl group, an n-butyl group, a sec-butyl group, a tert-butyl group or a trimethylsilyl group. R₂ and R₄ may independently represent hydrogen, a methyl group, an ethyl group, a propyl group, an n-butyl group, a sec-butyl group, a tert-butyl group or a trimethylsilyl group. Rm and Rn may independently represent a C₁-C₁₀ alkylene, a C₃-C₁₀ cycloalkylene or a C₄-C₁₀ aromatic hydrocarbon. M¹⁺ and M²⁺ may independently represent proton, an alkali metal ion or ammonium ion.

The disulfide compound may serve as a catalyst in a reductive reaction of copper to facilitate the deposition of copper. The disulfide compound represented by the above Chemical Formula (1) may include an alkylene adjacent to a sulfonate group, and at least one hydrogen atom which may be substituted with a C₂-C₄ alkyl group or a trimethylsilyl group. The substituted disulfide compound may be more stable than a disulfide compound having an unsubstituted alkylene adjacent to a sulfonate group so that the substituted disulfide compound may not be readily decomposed during a plating process. Therefore, the composition for plating copper including the substituted disulfide compound as an accelerator may have an increased life-time.

The disulfide compound may include, e.g., bis-(3-sulfo-3-methylpropyl)disulfide salts, bis-(3-sulfo-3-ethylpropyl)disulfide salts, bis-(3-sulfo-3-isopropyl)disulfide salts, bis-(3-sulfo-3-t-butylpropyl)disulfide salts, bis-(3-sulfo-3-trimethylsilylpropyl)disulfide salts, bis-(3-sulfo-3,3-dimethylpropyl)disulfide salts, bis-(3-sulfo-3,3-diethylpropyl) disulfide salts, bis-(2-sulfo-2-methylethyl)disulfide salts, bis-(2-sulfo-2-ethylmethyl) disulfide salts, bis-(4-sulfo-4-methylbutyl)disulfide salts, bis-(4-sulfo-4-ethylbutyl)disulfide salts, bis-(5-sulfo-5-methylpentyl)disulfide salts, bis-(6-sulfo-6-methylhexyl)disulfide salts, 3-sulfo-3-methylpropyl 4-sulfo-4-methylbutyl disulfide salts, 2-sulfo-2-methylpropyl 3-sulfo-3-methylpropyl disulfide salts, etc. These may be used alone or in a mixture thereof.

In an example embodiment, the disulfide compound may have a concentration of about 20 ppm to about 60 ppm. If the concentration of the disulfide compound is less than about 20 ppm, a copper plated layer may be adsorbed having a convex upper surface. If the concentration of the disulfide compound exceeds about 60 ppm, the cost of the composition for plating copper may be increased.

The suppressor may include a copolymer of polyethyleneoxide (PEO) and polypropyleneoxide (PPO). The copolymer of PEO and PPO may include, e.g., a PEO-PPO-PEO triblock copolymer, a PPO-PEO-PPO triblock copolymer, PEO/PPO-PPO/PEO-PEO/PPO tetrablock copolymer, a PPO/PEO-PEO/PPO-PPO/PEO tetrablock copolymer etc. The suppressor may have a weight average molecular weight of about 100 to about 100,000.

In an example embodiment, the PEO-PPO-PEO triblock copolymer may have a weight average molecular weight of about 300 to about 10,000 and a content of ethylene oxide (EO %) in the PEO-PPO-PEO triblock copolymer may be in a range of about 1 to about 99% (w/w). In another example embodiment, the PEO-PPO-PEO triblock copolymer may have a weight average molecular weight of about 2,500 to about 5,000 and a content of ethylene oxide (BO %) in the PEO-PPO-PEO triblock copolymer may be in a range of about 30 to about 60% (w/w).

In an example embodiment, the PEO-PPO-PEO triblock copolymer may have a concentration of about 40 ppm to about 100 ppm. If the concentration of the PEO-PPO-PEO triblock copolymer is less than about 40 ppm, the surface-roughness of a copper plated layer may be increased. If the concentration of the PEO-PPO-PEO triblock copolymer exceeds about 100 ppm, a subsequent plating process may not be easily perfo med due to an excessive inhibiting or suppressing effect.

The weight average molecular weight and the EO % of the copolymer may be properly adjusted so that a copper layer may be formed without generating a void therein in an opening, e.g., a via hole or a trench.

The leveler may include a betaine compound represented by the following Chemical Formula (2).

R₅-R₆N—R₇SO₃— Chemical Formula (2)

In Chemical Formula (2), R₅ may represent a C₁-C₄ alkyl group, an aromatic hydrocarbon group, a sulfonyl group, a phosphonyl group, an aldehyde group or a carbamide group. R₆ may represent a pyridine. R₇ may represent a C₁-C₄ alkyl, a cycloalkyl, and an aromatic hydrocarbon. R₇ may also represent a C₁-C₄ alkyl, a cycloalkyl, and an aromatic hydrocarbon which are substituted by one substituent selected from the group of a methyl group, an ethyl group, a propyl group, an isopropyl group, an n-butyl group, a sec-butyl group and a tert-butyl group.

The leveler may include, e.g., arylated polyethyleneimine (arylated PEI), sulfopropylated polyethyleneimine (Sulfopropylated PEI), lauryl dimethyl betaine, lauramidopropyl betaine, alkyl amine oxide, 1-(3-sulfopropyl)pyridinium betaine (PPS), 3-formyl-1-(3-sulfopropyl)pyridinium betaine (FPPS), isoquinoline 1-propanesulfonic acid (IQPS), 3-pyridinesulfonic acid (PYSA), nicotinamide N-propylsulfonate (NPS), etc. These may be used alone or in a mixture thereof.

In an example embodiment, the leveler may include arylated PEI having a concentration of about 0.01 to about 100 ppm. If the concentration of arylated PEI is less than about 0.01 ppm, the surface-roughness of a copper plated layer may be increased. If the concentration of arylated PEI exceeds about 100 ppm, a leveling effect of the leveler may be lessened.

Referring to FIG. 1, during the electroplating process, the plating solution mixture may be transferred into the plating bath 20 via the first plating solution transfer line 90. The plating solution mixture may be provided onto the substrate 100 at a flow rate of about 0.1 to about 300 L/min by the flow rate controller 70. The first plating solution transfer line 90 may be maintained at a temperature of about 20 to about 50° C. in order to prevent or inhibit the temperature of the plating solution mixture from being decreased. The substrate 100 may also be maintained at a temperature of about 20 to about 50° C. The substrate 100 may be rotated at a rate of about 2 rpm to about 100 rpm so that the plating solution mixture may be provided uniformly thereon.

The voltage supplier 60 may supply a voltage to the plating bath 20 so that a predetermined or given current may be applied to the plating solution mixture in the plating bath 20. Accordingly, the plating solution mixture may be decomposed to generate copper ions, and the copper ions may be adsorbed on the substrate serving as a cathode to form the copper plated layer 150. The plating solution mixture may be decomposed at a temperature of about 20 to about 50° C. and in a current density of about 0.1 to about 50 mA/cm².

After forming the copper plated layer 150, the remaining plating solution mixture may be transferred into the collector 80 via the plating solution collecting hole 24. The collected plating solution mixture may be reused after separation and/or purification processes.

Referring back to FIG. 4, a diffusion protection layer (not illustrated) according to an example embodiment may be further formed on a bottom and a sidewall of the opening 140 prior to forming the copper plated layer 150. The diffusion protection layer may prevent or inhibit copper atoms of the copper plated layer 150 from being diffused into the insulation layer 120 and the electrode pad 110. The diffusion protection layer may be formed using, e.g., titanium, titanium nitride, tantalum, tantalum nitride, tungsten nitride, tantalum silicide nitride, titanium silicide nitride, etc.

In another example embodiment, a seed layer (not illustrated) may be further formed on the bottom and the sidewall of the opening 140 prior to forming the copper plated layer 150. The seed layer may enhance the deposition rate of copper during the electroplating process for forming the copper plated layer 150. The seed layer may be formed using copper by a chemical vapor deposition (CVD) process or a physical vapor deposition (PVD) process. Alternatively, the seed layer may be formed using, e.g., gold (Au), silver (Ag), platinum (Pt) and/or ruthenium (Ru).

The composition for plating copper may include the PEO-PPO-PEO copolymer as a suppressor and arylated PEI as a leveler having a relatively strong suppressing ability and a leveling ability, respectively, even at a relatively high voltage. Therefore, the copper plated layer 150 including a highly planarized upper surface may be formed using the composition by the electroplating process performed at a rate of more than about 3 μm/min.

The mask 130 may be removed after forming the copper plated layer 150 to form a copper bump (not illustrated).

FIGS. 5 and 6 are top plan views illustrating the shape of the copper bump formed by the copper plating process.

Referring to FIG. 5, a plurality of first copper bumps 152 may have a pillar shape isolated from each other. In example embodiments, the first copper bump 152 may make contact with the electrode pad 110. The first copper bump 152 may have a cross-sectional area substantially the same as or wider than an upper surface area of the electrode pad 110.

Referring to FIG. 6, a plurality of second copper bumps 154 may have a line shape connected to external circuit terminals 156. The second copper bumps 154 may have planarized upper surfaces and may serve as wirings.

Referring to FIG. 7, solders 160 may be formed on the copper bumps 152 or 154. The solders 160 may be formed using, e.g., tin-silver (SnAg) by a CVD process or a PVD process. A semiconductor chip 170 may be attached to the solders 160.

As described above, the copper bumps 152 or 154 formed using the composition for plating copper may have highly planarized upper surfaces. Thus, the solders 160 formed on the copper bumps 152 or 154 may not be separated from the copper bumps 152 or 154 even at a higher temperature.

Hereinafter, the inventive concepts will be explained in detail with reference to the Examples and Comparative Example. However, the following Examples are illustrative, and it would be understood that various modifications are possible within the scope of the inventive concepts.

### Preparation of Compositions for Plating Copper

Compositions for plating copper serving as plating solutions in an electroplating process were prepared according to Examples 1 and 2, and Comparative Example.

### Example 1

An electrolyte solution including about 60 g/L of copper(II) sulfate pentahydrate (CuSO₄.5H₂O), about 50 g/L of sulfuric acid (H₂SO₄) and about 50 g/L of hydrochloric acid were prepared. A disulfide compound serving as an accelerator and a PEO-PPO-PEO triblock copolymer serving as a suppressor were added to the electrolyte solution, in which the disulfide compound and the triblock copolymer had concentrations of about 40 ppm and 80 ppm, respectively. The resultant mixture was sufficiently stirred to prepare a composition for plating copper. Pluronic® L62 (available from BASF Corporation; (EO)₅(PO)₃₀(EO)₅) having a weight average molecular weight of about 2,200 and an EO % of about 20% (w/w) was used as the suppressor. Bis-(3-sulfo-3-methylpropyl)disulfide dipotassium salt (Me-SPS) was used as the disulfide compound.

### Example 2

A composition for plating copper was prepared by a method substantially the same as that in Example 1, except that arylated polyethyleneimine serving as a leveler was further added to the electrolyte solution to have a concentration of about 10 ppm.

### Comparative Example

A composition for plating copper was prepared by a method substantially the same as that in Example 1, except that bis(3-sulfopropyl)disulfide disodium salt (SPS) was used instead of Me-SPS and polyethylene oxide (PEO) was used instead of the PEO-PPO-PEO triblock copolymer.

### Evaluation of the Flatness of a Copper Bump

Copper bumps were formed using the compositions of Examples 1 and 2, and the composition of the Comparative Example by an electroplating process.

Particularly, a silicon oxide layer including an electrode pad therein was formed on a substrate. A photoresist layer was formed on the silicon oxide layer, and the photoresist layer was partially removed to form an opening exposing the electrode pad and a photoresist pattern. A copper titanium nitride layer and a copper seed layer were sequentially formed on a bottom and a sidewall of the opening. A plating solution including the composition for plating copper was introduced into a plating bath. The substrate was immersed in the plating solution, and a copper electroplating process was perfomied. The copper electroplating process was performed at a room temperature, and the substrate was rotated at a rate of about 30 rpm. By the above process, a copper plated layer filling the opening was formed, and then the photoresist pattern was removed to form a copper bump.

Each surface-roughness of the copper blimps formed using the compositions of Examples 1 and 2, and the composition of the Comparative Example was measured while varying plating rate, current density and kinds of an accelerator, a suppressor and a leveler.

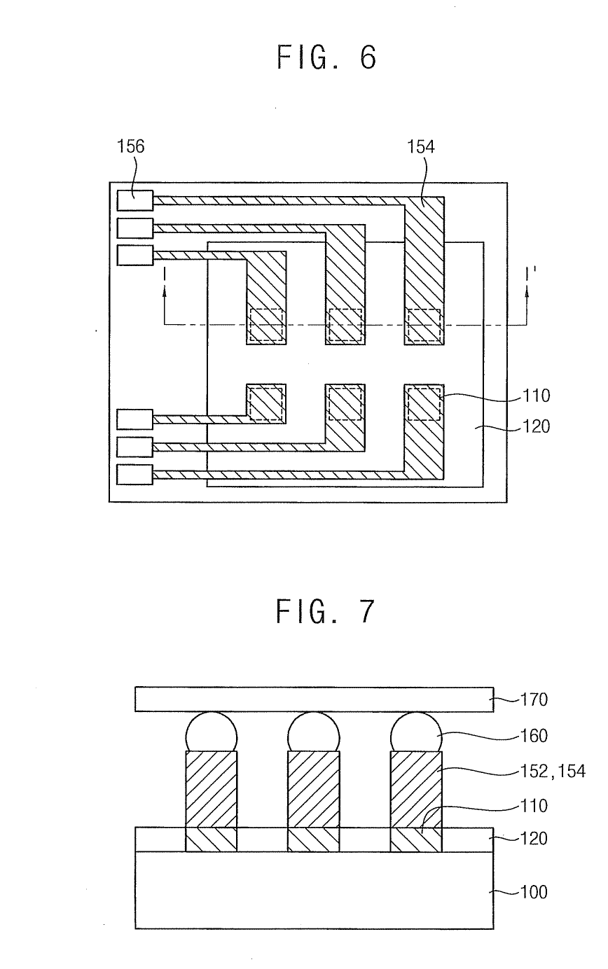

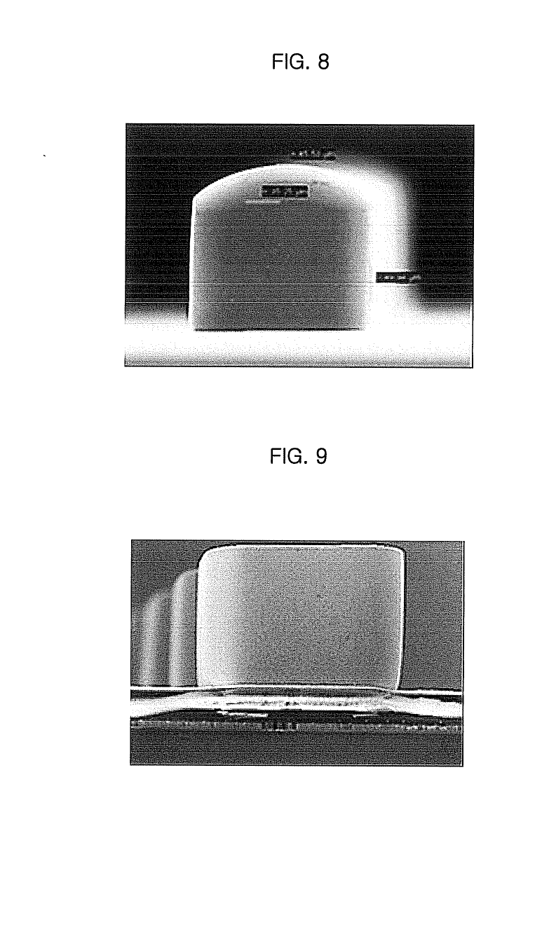

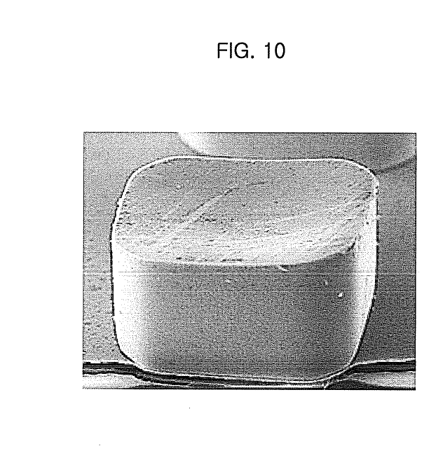

FIG. 8 is a scanning electron microscope (SEM) picture of a copper bump formed using the composition of Comparative Example. FIG. 9 is a SEM picture of a copper bump formed using the composition of Example 1. FIG. 10 is a SEM picture of a copper bump formed using the composition of Example 2.

TABLE 1

| Compositions for Plating Copper | | | | Surface-roughness | | |
|---|---|---|---|---|---|---|
| | Accel- | | | Plating Rate (μm/min) | | |
| | erator | Suppressor | Leveler | 1.5 | 3 | 4 |
| Example 1 | Me-SPS | PEO-PPO- | — | — | <5% | — |
| | | PEO | | | | |
| Example 2 | Me-SPS | PEO-PPO- | arylated | — | — | <5% |
| | | PEO | PEI | | | |
| Comparative | SPS | PEO | — | >30% | — | — |
| Example | | | | | | |

Referring to FIGS. 8 to 10 and Table 1, even though the plating rate was increased to be about 3 μm/min (current density: 16 ASD), the surface-roughness was lower than about 5% in Example 1. In Example 2, even though the plating rate was increased to be about 4 μm/min (current density: 24 ASD), the surface-roughness was lower than about 5%. However, in Comparative Example, the copper bump had a convex upper surface at the plating rate of about 1.5 μm/min in a relatively low current density, and the surface-roughness was more than about 30%.

As illustrated in the results of evaluating the surface-roughness, when the compositions of Examples 1 and 2 were used, the copper bumps had improved surface flatnesses at the plating rate more than about 1.5 μm/min in an increased current density. Particularly, the copper bump formed using the composition of Example 1 in which Me-SPS and the PEO-PPO-PEO copolymer were included as an accelerator and a suppressor, respectively, had an improved surface flatness at the plating rate of about 3 μm/min. The copper bump formed using the composition of Example 2 in which arylated PEI was further used as a leveler had an improved surface flatness even at the plating rate of about 4 μm/min. From the above results, it may be acknowledged that PEO used in Comparative Example is not stable relative to the PEO-PPO-PEO copolymer used in Examples 1 and 2 so that PEO may be decomposed at a relatively high voltage to have a reduced suppressing ability. Additionally, arylated PEI used as a leveler in Example 2 may not be decomposed even at a relatively high voltage to maintain a leveling ability thereof.

According to example embodiments, the composition for plating copper may include a PEO-PPO-PEO triblock copolymer having a relatively strong suppressing ability even in a higher current density as a suppressor so that a copper bump formed using the composition may have a highly planarized upper surface. Further, the composition may include arylated PEI as a leveler, an accelerator and an electrolyte solution having suitable concentrations so that the copper bump may have a reduced surface-roughness. Therefore, when a solder is formed on the copper bump, the solder may not be separated from the copper bump even at a higher temperature.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concepts. Accordingly, all such modifications are intended to be included within the scope of the present inventive concepts as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A composition for plating copper, comprising:
an electrolyte solution including a soluble copper salt, sulfuric acid and hydrochloric acid;
an accelerator including a disulfide compound, the disulfide compound having a concentration of about 20 to about 60 ppm;
a suppressor including a polyethyleneoxide (PEO)-polypropyleneoxide (PPO)-polyethyleneoxide (PEO) triblock copolymer, the PEO-PPO-PEO triblock copolymer having a concentration of about 40 to about 100 ppm, and a weight average molecular weight of about 300 to about 10,000; and
a leveler including arylated polyethyleneimine, the arylated polyethyleneimine having a concentration of about 0.01 to about 100 ppm.

2. The composition of claim 1, wherein the disulfide compound is represented by Chemical Formula (1): 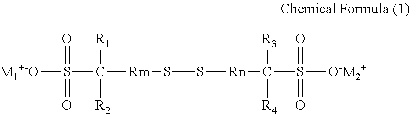
wherein, in the Chemical Formula (1), R₁ and R₃ independently represents a methyl group, an ethyl group, a propyl group, an isopropyl group, an n-butyl group, a sec-butyl group, a tert-butyl group or a trimethylsilyl group,
R₂ and R₄ independently represent hydrogen, a methyl group, an ethyl group, a propyl group, an n-butyl group, a sec-butyl group, a tert-butyl group or a trimethylsilyl group,
Rm and Rn independently represent a C₁-C₁₀ alkylene, a C₃-C₁₀ cycloalkylene or a C₄-C₁₀ aromatic hydrocarbon, and
M¹⁺ and M²⁺ independently represent a proton, an alkali metal ion or an ammonium ion.

3. The composition of claim 2, wherein the disulfide compound includes bis-(3-sulfo-3-methylpropyl)disulfide dipotassium salt (Me-SPS).

4. The composition of claim 1, wherein
the soluble copper salt includes copper (II) sulfate pentahydrate (CuSO₄.5H₂O), and
the electrolyte solution includes
about 50 to about 70 g/L of copper (II) sulfate pentahydrate,
about 40 to about 60 g/L of sulfuric acid, and
about 40 to about 60 g/L of hydrochloric acid.

5. The composition of claim 1, wherein the PEO-PPO-PEO triblock copolymer has a weight average molecular weight of about 2,500 to about 5,000 and a content of ethylene oxide (EO %) in a range of about 30 to about 60% (w/w).

6. A method of forming a copper bump, comprising:
forming an insulation layer on a substrate, the insulation layer including an electrode pad therein;
forming a mask on the insulation layer, the mask exposing the electrode pad through an opening; and
performing an electroplating process using a composition for plating copper to form a copper plated layer filling the opening,
the composition for plating copper including
an electrolyte solution including a soluble copper salt, sulfuric acid and hydrochloric acid;
an accelerator including a disulfide compound, the disulfide compound having a concentration of about 20 to about 60 ppm;
a suppressor including a polyethyleneoxide (PEO)-polypropyleneoxide (PPO)-polyethyleneoxide (PEO) triblock copolymer, the PEO-PPO-PEO triblock copolymer having a concentration of about 40 to about 100 ppm, and a weight average molecular weight of about 300 to about 10,000; and
a leveler including arylated polyethyleneimine, the arylated polyethyleneimine having a concentration of about 0.01 to about 100 ppm.

7. The method of claim 6, wherein the disulfide compound is represented by Chemical Formula (1): 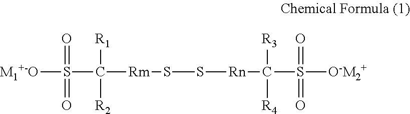
wherein, in the Chemical Formula (1), R₁ and R₃ independently represents a methyl group, an ethyl group, a propyl group, an isopropyl group, an n-butyl group, a sec-butyl group, a tert-butyl group or a trimethylsilyl group,
R₂ and R₄ independently represent hydrogen, a methyl group, an ethyl group, a propyl group, an n-butyl group, a sec-butyl group, a tert-butyl group or a trimethylsilyl group,
Rm and Rn independently represent a C₁-C₁₀ alkylene, a C₃-C₁₀ cycloalkylene or a C₄-C₁₀ aromatic hydrocarbon, and
M¹⁺ and M²⁺ independently represent proton, an alkali metal ion or ammonium ion.

8. The method of claim 7, the disulfide compound includes bis-(3-sulfo-3-methylpropyl)disulfide dipotassium salt (Me-SPS).

9. The method of claim 6, wherein
the soluble copper salt includes copper (II) sulfate pentahydrate (CuSO₄.5H₂O), and
the electrolyte solution includes
about 50 to about 70 g/L of copper (II) sulfate pentahydrate,
about 40 to about 60 g/L of sulfuric acid, and
about 40 to about 60 g/L of hydrochloric acid.

10. The method of claim 6, wherein the PEO-PPO-PEO triblock copolymer has a weight average molecular weight of about 2,500 to about 5,000 and a content of ethylene oxide (BO %) in a range of about 30 to about 60% (w/w).

11. The method of claim 6, wherein the performing the electroplating process comprises providing a plating solution that includes the composition for plating copper onto the substrate at a flow rate of about 0.1 to about 300 L/min.

12. The method of claim 6, wherein the electroplating process is performed at a plating rate of about 3 to about 4 μm/min.

13. The method of claim 6, wherein the substrate is maintained at a temperature of about 20 to about 50° C., and the substrate is rotated at a rate of about 2 to about 100 rpm during the electroplating process.

14. The method of claim 6, wherein the copper plated layer includes a plurality of copper plated layers in the shape of a pillar.

15. The method of claim 6, wherein the copper plated layer has a linear shape.

16. An electroplating apparatus comprising:
a plating bath configured to receive a plating solution containing a composition for plating copper on a substrate;
a supporter in an upper portion of the plating bath, the supporter configured to support the substrate and function as a cathode;
a dispersion plate in a lower portion of the plating bath, the dispersion plate configured to function as an anode; and
a voltage supplier connected to the supporter and the dispersion plate,
the composition for plating copper including
an electrolyte solution including a soluble copper salt, sulfuric acid and hydrochloric acid,
an accelerator including a disulfide compound, the disulfide compound having a concentration of about 20 to about 60 ppm,
a suppressor including a polyethyleneoxide (PEO)-polypropyleneoxide (PPO)-polyethyleneoxide (PEO) triblock copolymer, the PEO-PPO-PEO triblock copolymer having a concentration of about 40 to about 100 ppm, and a weight average molecular weight of about 300 to about 10,000; and
a leveler including arylated polyethyleneimine, the arylated polyethyleneimine having a concentration of about 0.01 to about 100 ppm.

17. The electroplating apparatus of claim 16, further comprising:
a mixer connected to the plating bath, the mixer configured to mix the composition for plating copper;
a flow rate controller connected to the mixer, the flow rate controller configured to adjust a flow rate of the plating solution;
a collector on sides of the plating path, the collector configured to collect or recycle the plating solution;
a first plating solution transfer line configured to connect the plating bath to the flow rate controller; and
a second plating solution transfer line configured to connect both the plating bath to the collector and the collector to the mixer.

18. The electroplating apparatus of claim 16, wherein the disulfide compound is represented by Chemical Formula (1): 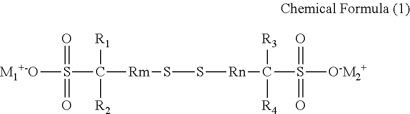
wherein, in the Chemical Formula (1), R₁ and R₃ independently represents a methyl group, an ethyl group, a propyl group, an isopropyl group, an n-butyl group, a sec-butyl group, a tert-butyl group or a trimethylsilyl group,
R₂ and R₄ independently represent hydrogen, a methyl group, an ethyl group, a propyl group, an n-butyl group, a sec-butyl group, a tert-butyl group or a trimethylsilyl group,
Rm and Rn independently represent a C₁-C₁₀ alkylene, a C₃-C₁₀ cycloalkylene or a C₄-C₁₀ aromatic hydrocarbon, and
M¹⁺ and M²⁺ independently represent a proton, an alkali metal ion or an ammonium ion.

19. The electroplating apparatus of claim 16, wherein
the soluble copper salt includes copper (II) sulfate pentahydrate (CuSO₄.5H₂O), and
the electrolyte solution includes
about 50 to about 70 g/L of copper (II) sulfate pentahydrate,
about 40 to about 60 g/L of sulfuric acid, and
about 40 to about 60 g/L of hydrochloric acid.

20. The electroplating apparatus of claim 16, wherein the PEO-PPO-PEO triblock copolymer has a weight average molecular weight of about 2,500 to about 5,000 and a content of ethylene oxide (BO %) in a range of about 30 to about 60% (w/w).
